(19) United States
(12) Patent Application Publication
(10) Pub. No.: US 2009/0309243 A1
(43) Pub. Date: Dec. 17, 2009

(54) MULTI-CORE INTEGRATED CIRCUITS HAVING ASYMMETRIC PERFORMANCE BETWEEN CORES

(75) Inventors: Phil Carmack, Santa Clara, CA (US); Brian Smith, Mountain View, CA (US)

Correspondence Address: NVIDIA C/O MURABITO, HAO & BARNES LLP, TWO NORTH MARKET STREET, THIRD FLOOR, SAN JOSE, CA, 95113, US

(73) Assignee: NVIDIA CORPORATION, Santa Clara, CA (US)

(21) Appl. No.: 12/137,053

(22) Filed: Jun. 11, 2008

(51) Int. Cl. H01L 23/58

(52) U.S. Cl. 257/798

(57) ABSTRACT

An integrated circuit in one embodiment includes asymmetric cores and an asymmetric core control circuit. At least one of the asymmetric cores is a different implementation of substantially the same function or subset of functionality as another core. The asymmetric core control circuit determines a performance parameter of an integrated circuit. The performance parameter may be the workload, the operating frequency, power consumption, quality of service, operating temperature or the like of the integrated circuit or a given portion of the integrated circuit. If the performance parameter is within a first range, the asymmetric core control circuit utilizes a first core to perform a function of the integrated circuit and idles a second core that is a different implementation of substantially the same function. If the performance parameter is within a second range, the core control circuit utilizes the second core to perform the function and idles the first core.

### BACKGROUND OF THE INVENTION

Integrated circuits (IC) typically include numerous passive and active components manufactured on a substrate material. Conventional ICs may include hundreds, thousands, millions or more semiconductor devices. As semiconductor technology has progressed, ICs have provided ever increasing performance. Furthermore, as semiconductor technology has progressed, it has generally been possible to decrease power consumption for the same level of performance. However, the increase in performance generally causes the power consumption in the IC to increase faster than technological improvements in decreasing power consumption. In addition, ICs may only operate at maximum performance a fraction of the time.

A number of techniques have been developed to increase performance and reduce power consumption. For example, sleep and standby modes, multithreading, multi-core and other techniques are currently employed to increase performance and/or decrease power consumption. Generally, techniques for reducing power or increasing performance are particularly suited for a given operating mode. Therefore, one of the biggest challenges in designing high performance IC, such as microprocessors, is trading off high performance and low power modes of operations. Accordingly, there is a continuing need to improve the tradeoff between high performance and low power modes of operation of ICs.

### SUMMARY OF THE INVENTION

Embodiments of the present technology are directed toward an integrated circuit having a plurality of asymmetric cores and methods of operation. In one embodiment, an integrated circuit includes a plurality of cores and an asymmetric core control circuit. At least one of the asymmetric cores is a different implementation capable of producing substantially the same function as another core. The asymmetric core control circuit sequences utilization of the asymmetric cores to meet one or more performance parameters of the integrated circuit.

In another embodiment, a method of dynamic operation of asymmetric cores in an integrated circuit includes determining a performance parameter of an integrated circuit. If the performance parameter is within a first range, a first core is utilized and a second core is idled. If the performance parameter is within a second range, the second core is utilized and the first core is idled.

In yet another embodiment, a method of operation of asymmetric cores in an integrated circuit includes determining a performance parameter of an integrated circuit. If the performance parameter is within a first range, a first instance of a given one of a plurality of core sets is utilized and a second instance of the given core set is idled. If the performance parameter is within a second range, the second instance of the given core set is utilized and the first instance of the core set is idled.

### BRIEF DESCRIPTION OF THE DRAWINGS

Embodiments of the present invention are illustrated by way of example and not by way of limitation, in the figures of the accompanying drawings and in which like reference numerals refer to similar elements and in which:

FIG. 1 shows a block diagram of an integrated circuit having a plurality of dynamically operable asymmetric cores, in accordance with one embodiment of the present technology.

FIG. 2 shows a flow diagram of a method of operation of asymmetric cores in an integrated circuit, in accordance with one embodiment of the present technology.

FIG. 3 shows a flow diagram of a method of operation of asymmetric cores in an integrated circuit, in accordance with another embodiment of the present technology.

FIG. 4 shows a flow diagram of a method of operation of asymmetric cores in an integrated circuit, in accordance with another embodiment of the present technology.

FIG. 5 shows a flow diagram of a method of operation of asymmetric cores in an integrated circuit, in accordance with yet another embodiment of the present technology.

### DETAILED DESCRIPTION OF THE INVENTION

Reference will now be made in detail to the embodiments of the present technology, examples of which are illustrated in the accompanying drawings. While the present technology will be described in conjunction with these embodiments, it will be understood that they are not intended to limit the invention to these embodiments. On the contrary, the invention is intended to cover alternatives, modifications and equivalents, which may be included within the scope of the invention as defined by the appended claims. Furthermore, in the following detailed description of the present technology, numerous specific details are set forth in order to provide a thorough understanding of the present technology. However, it is understood that the present technology may be practiced without these specific details. In other instances, well-known methods, procedures, components, and circuits have not been described in detail as not to unnecessarily obscure aspects of the present technology.

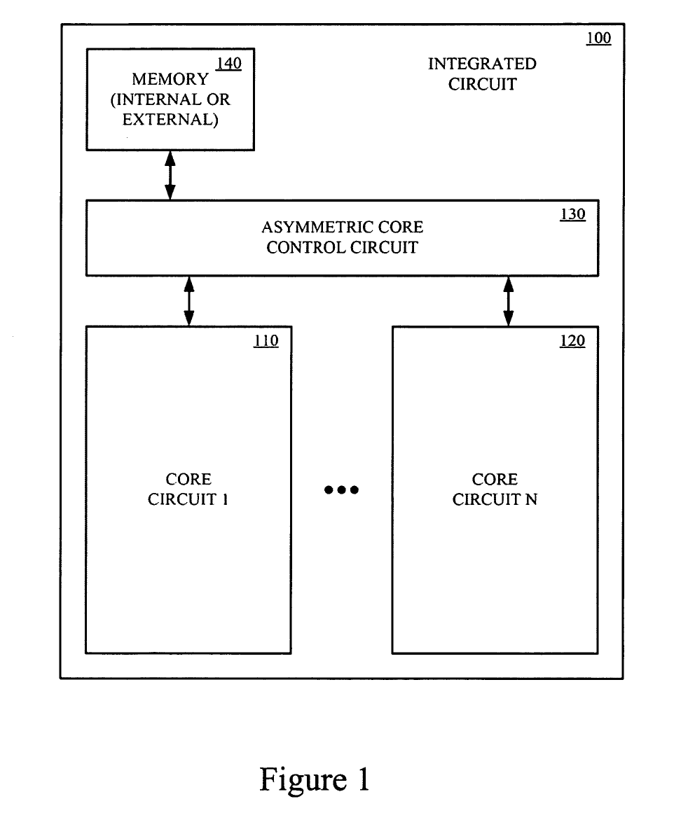

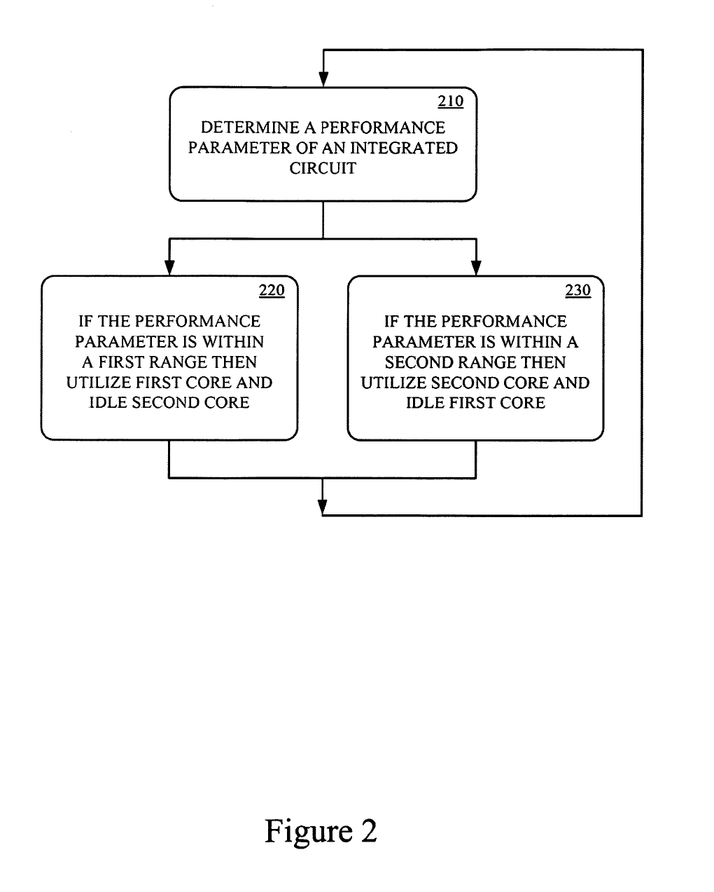

Referring to FIG. 1, an integrated circuit having a plurality of dynamically operable asymmetric cores, in accordance with one embodiment of the present technology, is shown. The integrated circuit (IC) 100 includes a plurality of cores 110, 120. Each core 110, 120 may implement substantially all the functionality of the IC 100. Alternatively, each given set of cores 110, 120 may implement a particular functional block of the IC 100, such as an arithmetic and logic unit, a fetch unit, a graphics pipeline, a rasterizer, or the like. It is also possible to have cores 110 and 120 capable of different functionality, but have a shared subset of functionality with a different implementation and trade-offs in usage of one versus another for providing this shared functionality. An example of this would be a CPU that can programmatically implement a function (e.g., multiplication of two numbers versus a set of logic that may also be capable of performing this function. The CPU may be capable of doing much more than just this simple multiplication. Similarly the logic circuit may also be capable of more than doing this simple multiplication. However, if the IC needs to perform this multiplication, the CPU or logic circuit may be chosen relative to their differing tradeoffs in power, throughput, latency and/or the like. A core control circuit 130 determines which one or more of the plurality of cores 110, 120 are utilized and which cores are idled. The core control circuit 130 sequences utilization of the one or more plurality of cores 110, 120 to meet one or more performance parameters of the IC 100. The performance parameters may include the workload, the operating frequency, response time, throughput, power consumption, operating temperature or the like. Operation of the integrated circuit in accordance with embodiment of the present technology will be further described with reference to FIGS. 2-5.

Referring now to FIG. 2, a method of dynamic operation of asymmetric cores in an integrated circuit, in accordance with one embodiment of the present technology, is shown. At 210, a performance parameter of the integrated circuit 100 is determined. The performance parameter may be the workload, the operating frequency, response time, throughput, power consumption, operating temperature or the like of the integrated circuit or a given portion of the integrated circuit. The performance parameter may be determined by an asymmetric core control circuit 130. At 220, a first core 110 of the integrated circuit 100 is utilized and a second core 120 is idled if the performance parameter is within a first predetermined range. At 230, the second core 120 is utilized and the first core 110 is idled if the performance parameter is within a second predetermined range.

Each core 110, 120 may implement substantially all the functionality of the IC. The first core 110, however, is a different implementation with respect to the second core 120 of substantially same functionality or a subset of functionality. The cores 110, 120 that are different implementations of substantially the same function or a subset of functionality are referred to herein as asymmetric cores. In one implementation, the first and second cores may be different hardware circuit designs. In another implementation, the first core may be a software implementation of the functionality and the second core may be a hardware implementation of the functionality. In yet another implementation, the first and second cores may be the same hardware design but utilize two different component device designs. For example, the first core 110 may be implemented using a high threshold voltage (Vt) transistor and the second core 120 may be implemented using a low threshold voltage (Vt) transistor. Depending upon the performance parameter, one of the asymmetric cores may offer substantial advantages over the other core.

The processes 210-230 may be selectively repeated a plurality of times during operation of the integrated circuit 100. In one implementation, the performance parameter is determined periodically (e.g., after a predetermined number of clock cycles). In another implementation, the performance parameter is determined for each input to the IC or the given cores. The process 220 or 230 is then performed in response to each time the performance parameter is determined. The system may switch between the first 110 and second core 120 and vice versa by transferring the internal context (or a subset of the context) of the first core 110 to the second core 120 and vice versa. In one implementation, the current context is written out to a temporary storage 140 by the core control circuit 130. The core to be utilized is then turned on and the core to be idled is turned off by the core control circuit 130. The context is then read into the core to be utilized by the core control circuit 130. A given core may be idled by turning off the power rail of the core, internally gating the power rail, back biasing the substrate of the core, gating the clock of the core, or the like.

In an exemplary implementation, a first core 110 is implemented using high threshold voltage (Vt) transistors and the second core 120 is implemented using low threshold voltage transistors. The low Vt transistors are characterized by lower switching delay and therefore may operate at higher frequencies than high Vt transistors. The low Vt transistor can also operate at lower supply voltages, which can be an advantage in dynamic power consumption (e.g., power consumption during switching) as compared to high Vt transistors operating at the same frequency. The high Vt transistors however are characterized by a lower leakage current as compared to the low Vt transistors. The lower leakage current of high Vt transistors reduces power consumption when the transistors are not switching. In many devices, minimizing leakage current may be a priority because the percentage of time the core is operated at peak performance is typically a fraction of the time that it must be available. For example, a CPU typically spends less time calculating a complex floating point algorithm than waiting for user input via the keyboard. The leakage current can also contribute to a larger fraction of total power consumption on more advanced processes operating at less aggressive frequencies.

The first core 110 implemented using high Vt transistors may therefore provide lower computational performance (e.g., lower operating frequency) with lower power consumption. The second core 120 implemented using low Vt transistors may in contrast provide higher computational performance. Depending on the workload, the first core 110 may be utilized and the second core 120 may be idled or vice verse. For example, when the workload is less than a specified level, the first core 110 (e.g., high Vt transistor design) is utilized and the power to the second core 120 could be turned off to reduce power consumption while handling the relatively low workload. When the workload exceeds a specified level, power to the second core 120 could be turned on and the context of the first core 110 transferred to the second core 120. Thereafter, the power to the first core 110 may be turned off.

The high workload that could not be efficiently handled by the first core 110 is therefore, provided by the second core 120. Accordingly, when dynamic power consumption begins to exceed leakage current based power consumption during operation of the first core 110 by a ratio that favors the second core 120, the asymmetric core control circuit 130 would transfer the internal context of the first core 110 to the second core 120. The asymmetric core control circuit 130 may transfer the internal context by causing core 110 to write its context out to temporary storage 140, such as in internal or external dynamic memory or direct transfer between the cores. As long as the asymmetric core control circuit 130 can transfer context between the cores with low enough latency to appear transparent to the usage, the IC 100 can achieve increased performance for a plurality of operating parameters over different operating conditions. For instance, the asymmetric cores could be utilized to reduce leakage current and therefore lower standby power consumption during the time it is performing low utilization tasks like waiting for a user input, while having the increased performance of the high frequency operation afforded by the low threshold voltage implementation core for tasks that are computationally complex.

Furthermore, embodiments of the present technology can be scaled to any number (N) of cores of varying mixes of power consumption and performance advantages. For instance, the IC may include low, medium and high performance cores. Additionally, it may be possible to use two or more cores in parallel to achieve even higher performance.

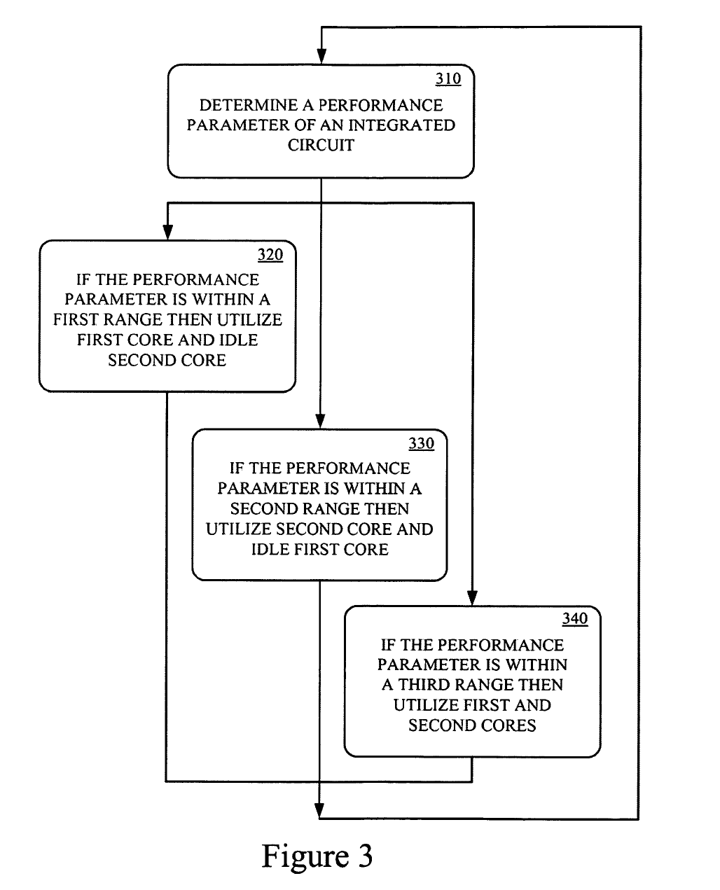

Referring now to FIG. 3, a method of dynamic operation of asymmetric cores in an integrated circuit, in accordance with another embodiment of the present technology, is shown. At 310, a performance parameter of the integrated circuit is determined. The performance parameter may be determined by the asymmetric core control circuit 130. At 320, a first core 110 of the integrated circuit is utilized and a second core 120 is idled if the performance parameter is within a first predetermined range. At 330, the second core 120 is utilized and the first core 110 is idled if the performance parameter is within a second predetermined range. At 340, both the first and second cores 110, 120 are utilized if the performance parameter is within a third predetermined range. Alternatively, the second core 120 and a third core may be utilized if the performance parameter is within a third predetermined range. The processes 310-340 may be selectively repeated a plurality of times during operation of the integrated circuit 100. In one implementation, the performance parameter is determined periodically. The decision to switch to a different core or set of cores, may use a form of hysteresis to avoid frequent switching of context. Alternatively, the decision can be based on meeting a maximum specified latency, a minimum throughput, quality of service and/or the like criteria. The system, for example, may start using a lower power configuration and switch to a higher power configuration only when necessary to meet system requirements, or start in a higher power configuration and switch to a lower power configuration when determining the system will exceed system requirements. In another implementation, the performance parameter is determined for each input to the cores. The process 320, 330 or 340 is then performed in response to each time the performance parameter is determined at 310.

For example, software executed in the asymmetric core control circuit 130 may distribute vector operations across both cores 110, 120 such that they can start at separate points. When both cores 110, 120 are utilized, the second core 120 would be given a fraction of the total work scaled to its performance advantage over the first core 110. For situations where the overhead of coordinating asymmetric cores becomes too high, the system can lower the peak frequency of the faster core 120 to match the maximum frequency of the slower core 110 to provide simple synchronous coordination between the cores.

Again, embodiments of the present technology can be scaled to any number (N) of cores of varying mixes of power consumption and performance advantages. For instance, the IC may include a low performance core and two or more high performance cores. During low workload, the low performance core may be utilized and the high performance cores may be idled. When the work load exceeds a first level, a first high performance core may be utilized and the low performance core could be idled. As the workload increase beyond the capability of the first high performance core, additional high performance cores could be utilized in combination with the first high performance core.

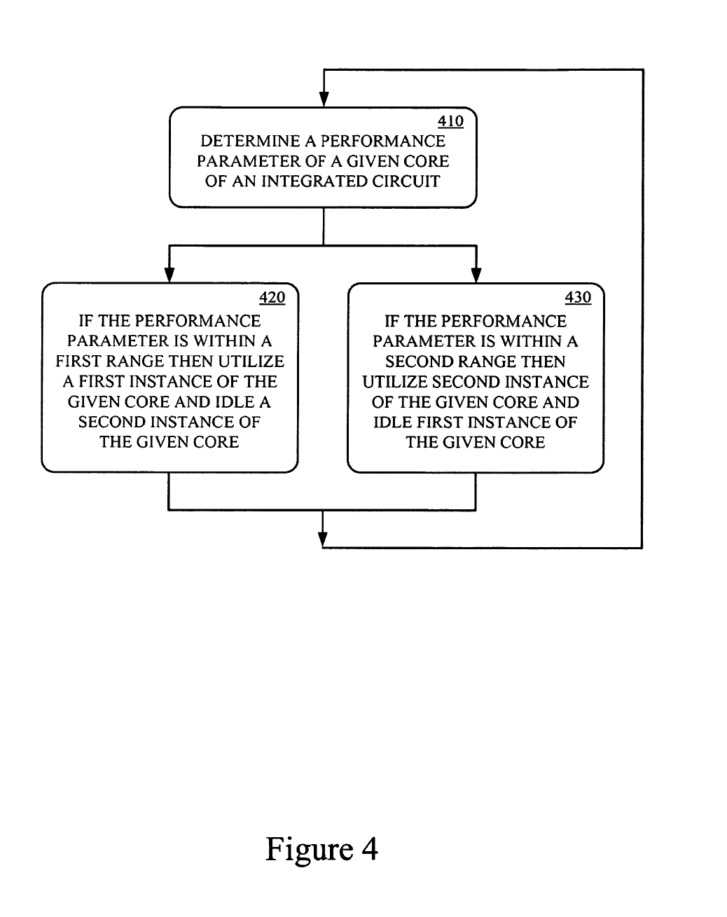

Referring now to FIG. 4, a method of dynamic operation of asymmetric cores in an integrated circuit, in accordance with another embodiment of the present technology, is shown. In the present embodiment, the integrated circuit includes a plurality of cores. At least one set of cores are different implementations of substantially the same functionality or a common subset of functionality. Each given set of cores may implement a particular functional block of the integrated circuit, such as an arithmetic and logic unit, a fetch unit, a graphics pipeline, a rasterizer, or the like. The first instance and second instance of the given set of cores, however, are different implementations of substantially the same functionality or a common subset of functionality, which are referred to herein as asymmetric cores. In one implementation, the first and second instances of the given core may be different hardware circuit designs. For example, the first instance of an adder core may be a bit-serial adder and the second instance may be a ripple-carry adder. In another example, the first instance may be implemented using a NMOS design and the second instance may be implemented using a CMOS design. In another implementation, the first instance may be a software implementation and the second instance may be a hardware implementation of substantially the same functionality. For example, the first instance may be a rasterizer implemented by software and the second instance may be a dedicated hardware rasterizer. In yet another implementation, the first and second instances may be the same hardware circuit design but each core utilizes a different component device designs. For example, the first instance of the given core may be implemented using a high Vt transistor and the second instance may be implemented using a low Vt transistor.

At 410, a performance parameter of the integrated circuit is determined. In one implementation, the performance parameter for a given core set is determined. The performance parameter may be determined by the asymmetric core control circuit 130. The performance parameter may be the workload, the operating frequency, response time, throughput, power consumption, operating temperature or the like of the integrated circuit or a given portion of the integrated circuit. At 420, a first instance of the given core 110 of the integrated circuit is utilized and a second instance of the given core 120 is idled if the performance parameter is within a first predetermined range. At 430, the second instance of the given core 120 is utilized and the first instance of the given core 110 is idled if the performance parameter is within a second predetermined range. Again, the processes 410-430 may be selectively repeated a plurality of times during operation of the integrated circuit 100.

In an exemplary implementation, the workload of a rasterizer is determined at 410. At 420, a first instance of the rasterizer, implemented using high Vt transistors, is utilized if the workload of the rasterizer is low. A second instance of the rasterizer, implemented using low Vt transistors, is idled when the workload of the rasterizer is low. For example, the workload of the rasterizer may be low when the image to be rendered is composed of a relatively low number/relatively large primitives. At 430, the low Vt transistor instance of the rasterizer is utilized if the workload of the rasterize is high. The high Vt transistor instance of the rasterizer is idled when the workload is high. For example, the workload of the rasterizer may be high when the image to be rendered is composed of a relatively large number/relatively small primitives.

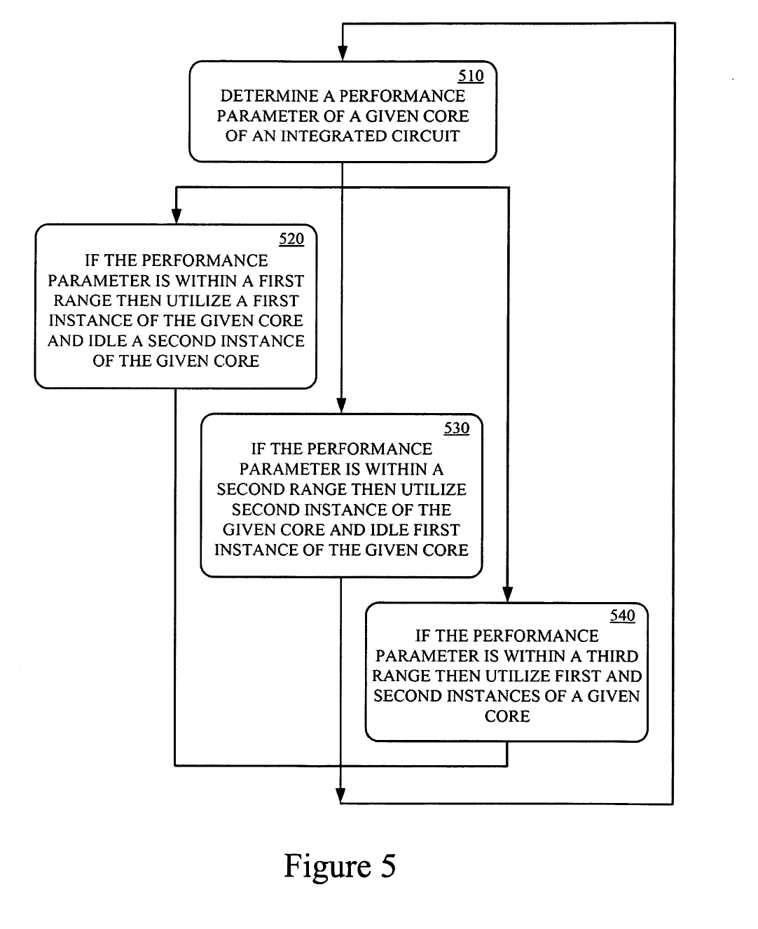

Referring now to FIG. 5, a method of dynamic operation of asymmetric cores in an integrated circuit, in accordance with another embodiment of the present technology, is shown. At 510, a performance of the integrated circuit is determined. In one implementation, the performance parameter for a given core set is determined. In another implementation, the performance parameter for the integrated circuit as a whole is determined. Again the performance parameter may be the workload, the operating frequency, response time, throughput, power consumption, operating temperature or the like, and may be determined by an asymmetric core control circuit 130. At 520, a first instance 110 of the given core set of the integrated circuit is utilized and a second instance of the core 120 is idled if the performance is within a first predetermined range. At 530, the second instance 120 of the given core is utilized and the first instance of the core 110 is idled if the performance parameter is within a second predetermined range. At 540, both the first and second instances 110, 120 of the given core set are utilized if the performance parameter is within a third predetermined range. The processes 510-540 may be selectively repeated a plurality of times under the control of the asymmetric core control circuit 130. In one implementation, the performance parameter is determined at 510 periodically. In another implementation, the performance is determined for each input to the given core set. The process 520, 530 or 540 is then performed in response to each time the workload is determined at 510.

Again, embodiments of the present technology can be scaled to any number (N) of cores of varying mixes of power consumption and performance advantages. For instance, the IC may include one or more sets of low, medium and high performance cores. In another instance, the IC may include one or more sets of cores, wherein at least one core in the set is a low performance core instance and two or more cores in the set are high performance core instances, or any other combination. The choice of the number of cores is a function of the trade off between the total area duplicated versus one or more other criteria such as the power savings for expected use cases, and the potential maximum capabilities of the highest performance core(s) or potential maximum capabilities of using all or a subset of cores in parallel.

Embodiments of the present technology advantageously utilize asymmetric cores to provide increase performance and/or decrease power consumption in response to one or more operating parameters. Depending upon the performance parameter, a one or more asymmetric cores that offer substantial advantages over one or more of the other asymmetric cores are dynamically utilized. When one or more of the operating parameters change, the context running on one or more asymmetric cores can be advantageously switched to the other asymmetric cores. The dynamic sourcing of the asymmetric cores improves the tradeoff between high performance and low power modes of the ICs.

The foregoing descriptions of specific embodiments of the present technology have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the present technology and its practical application, to thereby enable others skilled in the art to best utilize the present technology and various embodiments with various modifications as are suited to the particular use contemplated. It is intended that the scope of the invention be defined by the Claims appended hereto and their equivalents.

What is claimed is:

1. An integrated circuit comprising:
a first core circuit;
a second core circuit, wherein the second core circuit is a different implementation capable of producing substantially the same functionality as the first core circuit or a common subset of functionality of the first core circuit; and
an asymmetric core control circuit coupled to the first and second core circuits for sequencing utilization of the first and second core circuits to meet one or more performance parameters of the integrated circuit.

2. The integrated circuit of claim 1, wherein the first and second core circuits implement substantially all the functionality of the integrated circuit.

3. The integrated circuit of claim 1, wherein the first and second core circuits implement a particular functional block of the integrated circuit.

4. The integrated circuit of claim 1, wherein the one or more performance parameters include a workload, operating frequency, response time, throughput, quality of service, power consumption, and operating temperature.

5. The integrated circuit of claim 1, wherein the first core circuit is implemented using higher threshold voltage transistors than the second core circuit.

6. The integrated circuit of claim 1, further comprising memory for storing a context when switching between the first and second core circuits in response to sequence utilization of the first and second core circuits.

7. A method comprising:
determining a performance parameter of an integrated circuit;
utilizing a first core of the integrated circuit and idling a second core of the integrated circuit if the performance parameter is within a first range, wherein the first core is a different implementation capable of producing substantially the same functionality as the second core; and
utilizing the second core and idling the first core if the performance parameter is within a second range.

8. The method according to claim 7, further comprising utilizing the first and second cores if the performance parameter is within a third range.

9. The method according to claim 7, further comprising utilizing the second core and a third core of the integrated circuit and idling the first core if the performance parameter is within a third range.

10. The method according to claim 7, wherein the performance parameter is selected from a group consisting of workload, operating frequency, response time, throughput, quality of service, power consumption, and operating temperature.

11. The method according to claim 7, wherein the first and second cores implement substantially all the functionality of the integrated circuit.

12. The method according to claim 7, wherein the performance parameter is determined a plurality of times during operation of the integrated circuit.

13. The method according to claim 7, further comprising:
switching from the first core to the second core by turning on the second core, transferring the context of the first core to the second core and idling the first core; and
switching from the second core to the first core by turning on the first core, transferring the context of the second core to the first core and idling the second core.

14. A method comprising:
determining a performance parameter of an integrated circuit;
utilizing a first instance of a given core set of the integrated circuit and idling a second instance of the given core set of the integrated circuit if the performance parameter is within a first range, wherein the first instance of the given core set is a different implementation of substantially the same functionality as the second instance of the given core set; and
utilizing the second instance of the given core set and idling the first instance of the core set if the performance parameter is within a second range.

15. The method according to claim 14, further comprising utilizing the first and second instance of the given core set if the performance parameter is within a third range.

16. The method according to claim 14, further comprising utilizing the second instance of the given core set and a third instance of the given core set of the integrated circuit and idling the first instance of the given core set if the performance parameter is within a third predetermined range.

17. The method according to claim 14, wherein the integrated circuit includes a plurality of sets of cores, each set implements a different functional block of the integrated circuit and the first and second instance of the given core set implement a particular functional block of the integrated circuit.

18. The method according to claim 14, wherein determining the performance parameter of an integrated circuit comprises determining the performance parameter for the given core set.

19. The method according to claim 14, wherein the performance parameter is determined for each input to the given core set.

20. The method according to claim 14, wherein the performance parameter is determined periodically.
